(19) United States
(12) Patent Application Publication
(10) Pub. No.: US 2003/0096200 A1
(43) Pub. Date: May 22, 2003

(54) Method of forming isolated lines using multiple exposure

(75) Inventor: Chun-Cheng Liao, Panchiao City (TW)

Correspondence Address: Richard P. Berg, Esq., c/o LADAS & PARRY, Suite 2100, 5670 Wilshire Boulevard, Los Angeles, CA, 90036-5679, US

(73) Assignee: NANYA TECHNOLOGY CORPORATION

(21) Appl. No.: 10/071,060

(22) Filed: Feb. 7, 2002

(30) Foreign Application Priority Data
Nov. 19, 2001 (TW) 90128591

(51) Int. Cl. G03F 7/20

(52) U.S. Cl. 430/394; 430/396; 430/313

(57) ABSTRACT

The present invention provides a method of forming isolated lines using multiple exposure. A substrate covered by a resist layer is provided, and a plurality of first line patterns is defined on the resist layer using a patterning mask. Subsequently, the patterning mask is shifted a predetermined distance in a horizontal direction, thereby defining a plurality of second line patterns on the resist layer to make a part of the second line patterns overlap the first line patterns to form a plurality of overlapping line patterns, the overlapping line patterns having a predetermined line width. Finally, development is performed to form the overlapping line patterns in the resist layer.

### BACKGROUND OF THE INVENTION

1. Field of the Invention

The present invention relates in general to an exposure. In particular, the present invention relates to the formation of isolated lines using multiple exposure to obtain finer width of isolated lines and larger process window.

2. Description of the Related Art

In semiconductor integrated circuit (IC) production, photolithography is very important for precisely defining designed patterns to a resist layer. After photolithography, the resist patterns are transferred to a semiconductor substrate by etching and then a desired circuit structure is obtained. In general, photolithography includes the steps of priming, resist coating, prebake (i.e., soft bake), exposing, post exposure treatment (PET), development, and hard bake, etc. In the exposure step, however, resolution is a critical element in deciding the integration of semiconductor devices. Accordingly, many semiconductor manufacturers conduct research and development to promote photolithography technology.

In recent years, with the increasing miniaturization of semiconductor devices, design rule of line width and space between lines or devices becomes finer. However, the width is subject to optical characteristics. To obtain fine sized devices in the exposure, the interval between transparent regions in a mask is scaled down with device size. When the light passes through the mask, diffraction occurs and reduces resolution. Moreover, when light passes through the transparent regions of a mask having different interval sizes, the light through the regions having small interval sizes is influenced by the transparent regions having large interval sizes and results in deformation of the transfer pattern.

FIG. 1 shows an exposure-defocus tree (E-D Tree) diagram for 0.35 micron-process. The vertical axial represents line width value, and covers a range of 0.315 micrometer (μm) to 0.385 μm (i.e., 0.35 μm±10%). The horizontal axial represents defocus value. TDOF represents total depth of focus. W represents a process window under different energy densities of irradiation such as 100 mJ/cm² and 120 mJ/cm². In traditional photolithography, isolated lines cannot produce larger process window W size.

Accordingly, in order to obtain finer isolated lines and larger process window W size, optical proximity correction (OPC) is used to change designed patterns of a mask or use assistant patterns on a mask. Although the improved method can obtain finer isolated lines, it cannot obtain larger process window size.

### SUMMARY OF THE INVENTION

The object of the present invention is to provide a method of forming isolated lines using multiple exposure to obtain finer isolated lines.

Another object of the present invention is to provide a method of forming isolated lines using multiple exposure to obtain larger process window size.

To achieve the above-mentioned objects, the present invention provides a method of forming isolated lines using multiple exposure comprising the steps of providing a substrate with a surface covered by a resist layer, defining a plurality of first line patterns on the resist layer using a patterning mask, shifting the patterning mask a predetermined distance in a horizontal direction, thereby defining a plurality of second line patterns on the resist layer to make a part of the second line patterns overlap the first line patterns to form a plurality of overlapping line patterns, the overlapping line patterns having a predetermined line width, and performing development to form overlapping line patterns in the resist layer. Moreover, a predetermined space separates the overlapping line patterns. The mask size of the patterning mask is substantially twice the sum of the predetermined line width and the predetermined space. In addition, the predetermined distance is substantially equal to half the sum of the predetermined line width and the predetermined space less the predetermined line width.

### BRIEF DESCRIPTION OF THE DRAWINGS

The present invention will become more fully understood from the detailed description given herein below and the accompanying drawings, given by way of illustration only and thus not intended to be limitative of the present invention.

FIG. 1 is an exposure-defocus tree (E-D Tree) diagram for 0.35 micron-process.

FIG. 2 is a schematic view showing a plurality of first line patterns defined on a resist layer in accordance with the embodiment of the present invention.

FIG. 3 is a schematic view showing a plurality of overlapping line patterns defined on the resist layer in accordance with the embodiment of the present invention.

FIG. 4 is a schematic view showing a plurality of overlapping line patterns formed in the resist layer after development in accordance with the embodiment of the present invention.

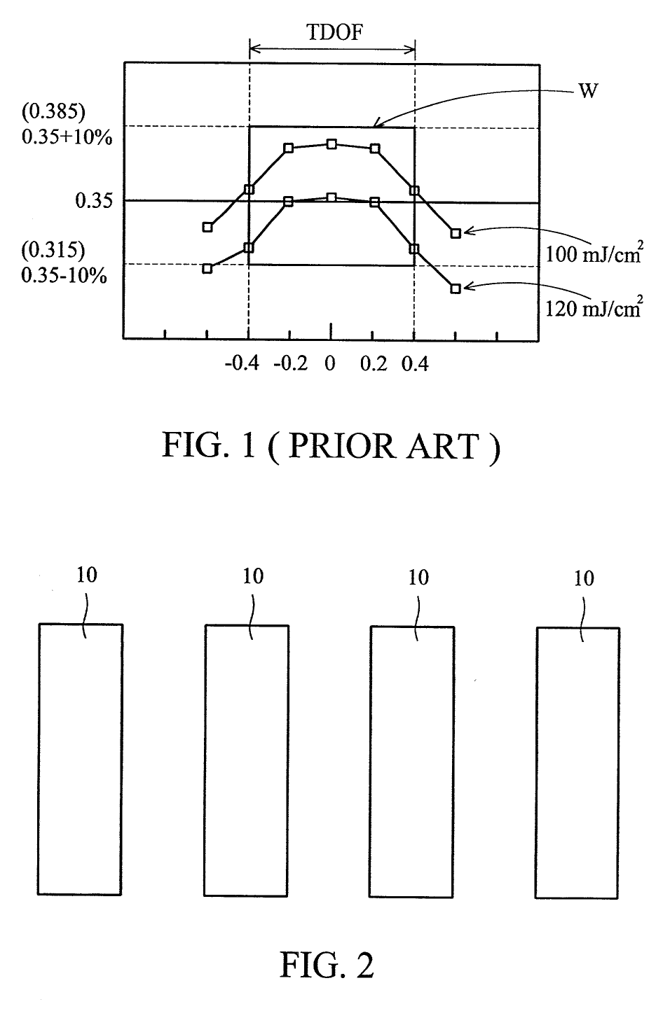

### DETAILED DESCRIPTION OF THE PREFERRED EMBODIMENT

The present invention uses double exposure to form isolated lines with larger process window size (i.e., process margin).

As shown in FIG. 2, a semiconductor substrate (not shown) is provided. A resist layer (not shown) such as positive photoresist or negative photoresist is formed on the surface of the substrate by traditional spin-coating. In the present embodiment, a positive photoresist is used. Subsequently, an exposure is performed with a patterning mask (not shown) to define a plurality of first line patterns 10 on the resist layer.

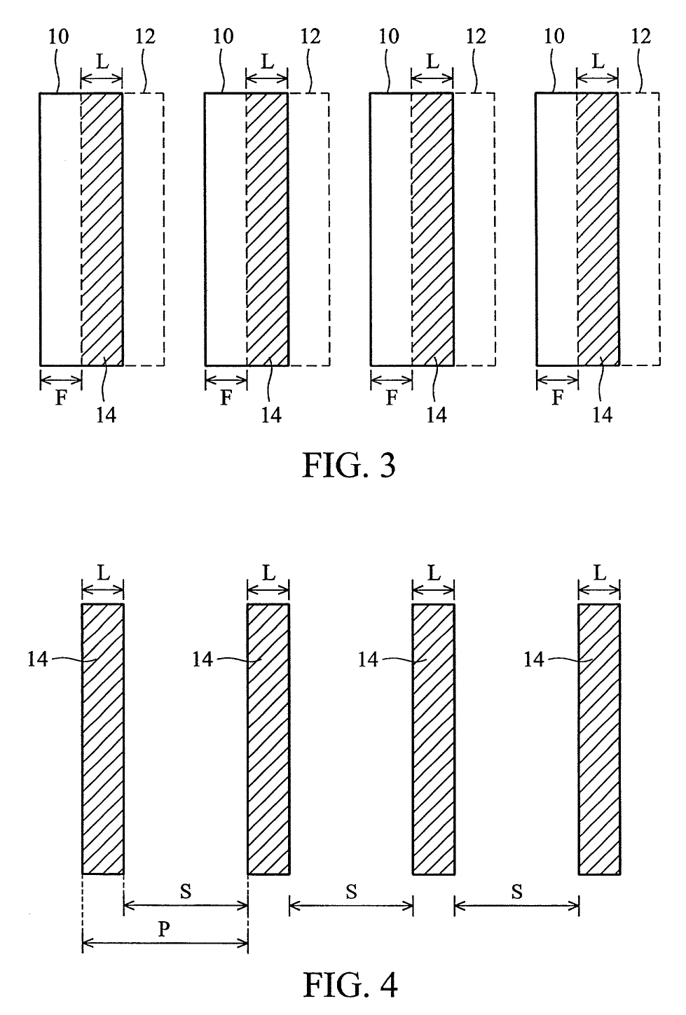

As shown in FIG. 3, the patterning mask is shifted a predetermined distance F. Next, the exposure is performed again to define a plurality of second line patterns 12 on the resist layer and makes part of the second line patterns overlap the first line patterns. As a result, a plurality of overlapping line patterns 14 is formed, and the overlapping line patterns have a predetermined line width L.

As shown in FIG. 4, development is performed to form overlapping line patterns 14 in the resist. S represents a predetermined space between the overlapping line patterns. P represents the sum of the predetermined line width L and the predetermined space S.

In this embodiment, the mask size of the patterning mask is substantially twice P. In other words, the sum of the predetermined line width L and the predetermined space S is substantially equal to half the mask size. In addition, the predetermined distance F that the patterning mask shifts as mentioned above is substantially equal to half the sum of the predetermined line width L and the predetermined space S less the predetermined line width L. That is, the predetermined distance F is substantially equal to half P less the predetermined line width L. Also, in this embodiment, width of the first and second line patterns are the same and both are equal to half P. To sum up the relationship, the present invention disposes the following formulas:

Mask size=2×P 1.

F≡P/2−L 2.

Where P=L+S

As an example, a designed isolated line pattern may have line width of 0.1 μm (i.e., the predetermined line width L) and line space of 0.3 μm (i.e., the predetermined space S). According to the formulas of the present invention, the predetermined distance F that the patterning mask must shift is equal to half P less L (i.e., (0.1+0.3)/2 μm−0.1 μm=0.1 μm) . In addition, the mask size of the patterning mask is equal to twice P (i.e., 2×(0.1+0.3)=0.8 μm), and the line width of both the first and second line patterns is half P (i.e., (0.1+0.3)/2 μm=0.2 μm).

Therefore, taking desired width and space of the isolated lines into the formulas according to the method of the present invention, the line width of the first line patterns and the predetermined distance F that the patterning mask need to shift are obtained. Finer isolated lines and larger process window size can be obtained using double exposure according to the present invention.

It is to be understood that the present invention is not limited to the embodiment described above, but encompasses any and all embodiments within the scope of the following claims.

What is claimed is:

1. A method of forming isolated lines using multiple exposure, comprising steps of:
providing a substrate with a surface covered by a resist layer;
defining a plurality of first line patterns on the resist layer using a patterning mask;
shifting the patterning mask predetermined distance in a horizontal direction, thereby defining a plurality of second line patterns on the resist layer to make a part of the second line patterns overlap the first line patterns to form a plurality of overlapping line patterns, the overlapping line patterns having a predetermined line width; and
performing development to form the overlapping line patterns in the resist layer.

2. The method as claimed in claim 1, wherein the substrate is a semiconductor substrate.

3. The method as claimed in claim 1, wherein the resist layer is a positive photoresist.

4. The method as claimed in claim 1, wherein the resist layer is a negative photoresist.

5. The method as claimed in claim 1, wherein a predetermined space separates the overlapping line patterns.

6. The method as claimed in claim 5, wherein the size of the patterning mask is substantially twice the sum of the predetermined line width and the predetermined space.

7. The method as claimed in claim 5, wherein the predetermined distance is substantially equal to half the sum of the predetermined line width and the predetermined space less the predetermined line width.

8. A method of forming isolated lines using multiple exposure, comprising steps of:
providing a substrate with a surface covered by a resist layer;
defining a first line pattern on the resist layer using a patterning mask;
shifting the patterning mask a predetermined distance in a horizontal direction, thereby defining a second line pattern on the resist layer to make a part of the second line pattern overlap the first line pattern to form an overlapping line pattern, the overlapping line pattern having a predetermined line width; and
performing development to form the overlapping line pattern in the resist layer.

9. The method as claimed in claim 8, wherein the substrate is a semiconductor substrate.

10. The method as claimed in claim 8, wherein the resist layer is a positive photoresist.

11. The method as claimed in claim 8, wherein the resist layer is a negative photoresist.
